(19) United States
(12) Patent Application Publication
(10) Pub. No.: US 2023/0411461 A1
(43) Pub. Date: Dec. 21, 2023

(54) GAN DEVICE WITH EXTENDED DRAIN CONTACT

(71) Applicant: TEXAS INSTRUMENTS INCORPORATED, Dallas, TX (US)

(72) Inventors: Dong Seup Lee, McKinney, TX (US); Qhalid Fareed, Plano, TX (US)

(73) Assignee: TEXAS INSTRUMENTS INCORPORATED, Dallas, TX (US)

(21) Appl. No.: 17/806,959

(22) Filed: Jun. 15, 2022

(51) Int. Cl. H01L 29/20; H01L 29/66; H01L 29/778; H01L 21/02

(52) U.S. Cl. CPC H01L 29/2003; H01L 29/66462; H01L 29/7786; H01L 21/0254

(57) ABSTRACT

A semiconductor device is described herein. The semiconductor device comprises a silicon substrate layer. The semiconductor device comprises a first semiconductor layer comprising a gallium nitride layer, the first semiconductor layer disposed over the silicon substrate layer. The semiconductor device comprises a second semiconductor layer disposed on the first semiconductor layer, the second semiconductor layer comprising an aluminum gallium nitride layer. The semiconductor device comprises a first drain contact extending through the second semiconductor layer and extending into the first semiconductor layer.

### TECHNICAL FIELD

Examples of the present disclosure generally relate to semiconductor devices and, in particular, to manufacturing gallium nitride (GaN)-based semiconductor devices.

### BACKGROUND

Gallium nitride (GaN) based semiconductor devices deliver characteristics that are better than silicon-based devices. GaN-based semiconductor devices have faster-switching speed and excellent reverse-recovery performance which is critical for low-loss and high-efficiency performance

### SUMMARY

This Summary is provided to comply with 37 C.F.R. § 1.73, requiring a summary of the invention briefly indicating the nature and substance of the invention. It is submitted with the understanding that it will not be used to interpret or limit the scope or meaning of the claims.

Certain aspects of the subject matter described in this disclosure can be implemented in a semiconductor device. The semiconductor device comprises a silicon substrate layer. The semiconductor device comprises a first semiconductor layer comprising a gallium nitride layer, the first semiconductor layer disposed over the silicon substrate layer. The semiconductor device comprises a second semiconductor layer disposed on the first semiconductor layer. The semiconductor device comprises a first drain contact extending through the second semiconductor layer and extending into the first semiconductor layer.

Certain aspects of the subject matter described in this disclosure can be implemented in a method for manufacturing a semiconductor device. The method comprises forming a first semiconductor layer on a semiconductor substrate, the first semiconductor layer comprising a gallium nitride layer. The method includes forming a second semiconductor layer on the first semiconductor layer, the second semiconductor layer comprising an aluminum gallium nitride layer. The method includes forming a mask layer on the second semiconductor layer, the mask layer comprising an opening exposing the second semiconductor layer. The method includes forming a drain contact using the opening of the mask layer exposing the second semiconductor layer, the drain contact extending through the second semiconductor layer and into the first semiconductor layer.

Certain aspects of the subject matter described in this disclosure can be implemented in a structure. The structure includes a gallium nitride layer disposed on a silicon substrate. The structure includes an aluminum gallium nitride layer disposed on the gallium nitride layer. The structure includes a silicon nitride layer disposed on the aluminum gallium nitride layer. The structure includes at least one metallization layers disposed in the silicon nitride layer, the at least one metallization layers forming a drain electrode, a gate electrode, and a source electrode. The structure includes at least one drain terminal extending through the silicon nitride layer and aluminum gallium nitride layer and into the gallium nitride layer, the at least one drain terminal coupled to the drain electrode.

These and other aspects may be understood with reference to the following detailed description.

### BRIEF DESCRIPTION OF THE DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 is a cross-section of a gallium nitride (GaN)-based semiconductor device.

FIG. 2 is a cross-section of a GaN-based semiconductor device with a modified design, according to some examples.

FIG. 3 is an example GaN-based semiconductor device with a modified design, according to some examples.

FIG. 4 is a cross-sectional view of a semiconductor device having the modified design, according to some examples.

FIG. 5A-5D illustrate exemplary semiconductor devices with drain contract structures of differing depths, according to some examples.

FIG. 6A-6F are top cross-sectional views of GaN-based semiconductor devices, according to some examples.

FIG. 7 illustrates the electrical potential distribution of a GaN-based semiconductor device, according to some examples.

FIG. 8 is a flowchart of operations for manufacturing a semiconductor device, according to some example.

FIG. 9A-9H are cross-sectional views of a semiconductor device being manufactured with the modified design, according to some examples.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the description or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

Some semiconductor devices (e.g., transistors) include a layer of highly-mobile electrons, which are induced by forming a heterostructure including a group III nitride-based alloy with broader band-gap (e.g., aluminum gallium nitride (AlGaN)) grown over another group III nitride material with a narrower bandgap (e.g., GaN). The large conduction-band offset, spontaneous polarization, and piezoelectric polarization in such a heterostructure induce a highly-mobile 2-dimensional electron gas (2DEG) at their interface. For the sake of illustration, some of the description herein focuses on AlGaN/GaN heterostructures. However, this description is not limited to AlGaN/GaN-based heterostructures and can be applied to other heterostructures that can induce the 2DEG at their interface. Existing semiconductor fabrication techniques can be used to manufacture transistors using AlGaN/GaN-based heterostructures on a substrate (e.g., a semiconductor wafer).

Some GaN-based transistors are fabricated such that the 2DEG is formed between the source and drain contact structures of the GaN-based transistor. A gate contact structure is generally positioned between the source and drain contact structures. With some GaN-based transistors, a depletion region forms under the gate contact structure at the AlGaN/GaN interface, meaning that electrons under the gate contact structure are depleted.

In high-voltage (e.g., operating voltage over 500V) applications, the transistors suffer from the back-gating effect in that a depletion region forms in a region under/around the drain contact structure due to a relative negative bias between the 2DEG and the substrate. Thus, the transistor suffers from the back-gating effect, which can result in the depletion region extending to the drain contact structure, which can then lead to failure of the transistor. Some GaN-based transistors are more prone to failure because the design of these GaN-based transistors permits a relative low electron density in their 2DEG. Consequently, the depletion region forms and eventually extends to the drain contact structure at a voltage lower than the operating voltage. Furthermore, severe back-gating effect causes reliability issues, such as dynamic drain-source on-state resistance (R_{DSON}) and safe operating area (SOA) degradation.

Accordingly, at least some of the examples disclosed herein are directed towards transistors with a modified design to address the back-gating effect. At least some of the examples are directed towards GaN-based transistors. In at least some examples, the design includes an extended drain contact structure in a GaN layer of the GaN-based transistors. The extended drain contact structure shields the vertical electrical field in the 2DEG channel, thus preventing back-gating and reducing the channel depletion.

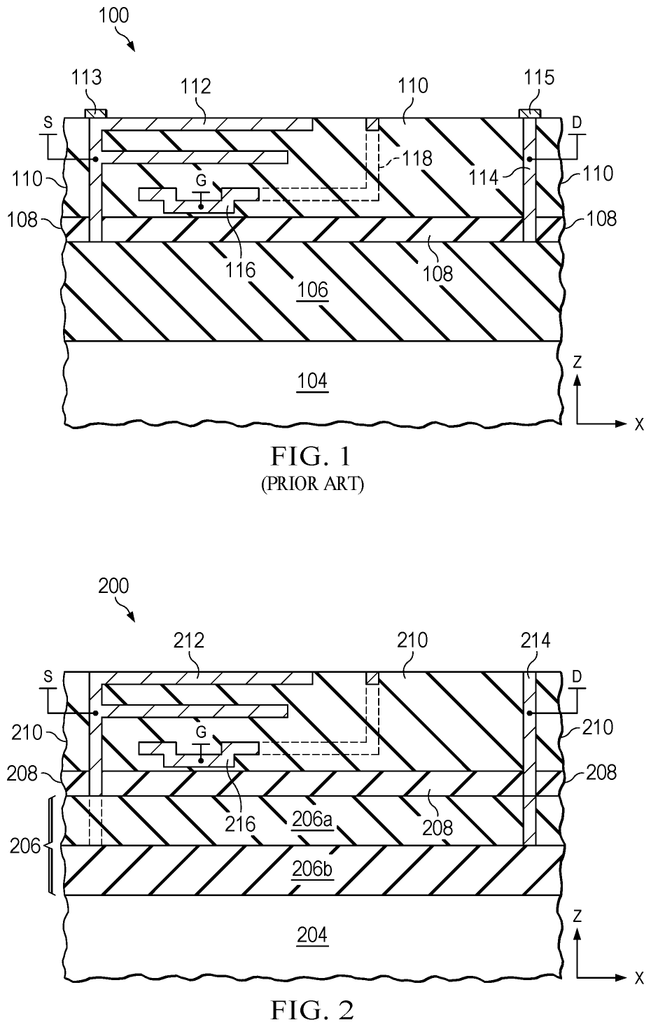

FIG. 1 is a cross-section of an GaN-based transistor. The example transistor 100 is a GaN-based structure, including a silicon (Si) substrate 104, and a GaN layer 106 formed on an upper side of the silicon substrate 104. The transistor 100 includes an AlGaN layer 108 formed on an upper side of the GaN layer 106. The GaN layer 106 and the AlGaN layer 108 form a heterojunction with a junction between two materials with different band gaps. The junction provides a channel for the transistor 100. A silicon nitride (SiN) layer 110 is formed on a top side of the AlGaN layer 108.

The transistor 100 includes a source contact structure connected to a first conductive feature 113 having a portion accessible at a top side of the transistor 100. The transistor 100 includes a drain contact structure 114 connected to a second conductive feature 115 having a portion accessible at the top side of the transistor 100.

The source contact structure 112 and the drain contact structure 114 extend through the AlGaN layer 108 but do not extend into the GaN layer 106. As illustrated in FIG. 1, the source contact structure 112 and the drain contact structure 114 have similar structures and features. Accordingly, the source contact structure 112 and the drain contact structure only extend to the surface of the GaN layer 106.

Current collapse can increase the RDSON due to charge trapping in high voltage GaN transistors (e.g., the transistor 100), for example, because of hot electrons created during hard switching at high voltages and/or leakage current flowing during the off state. In some examples, the severe back-gating effect in the illustrated GaN transistor 100 depletes the 2DEG channel faster. The depletion of the 2DEG channel can cause reliability issues, such as dynamic RDSON and SOA degradation.

FIG. 2 is a cross-section of a semiconductor device 200 with an GaN-based transistor with a modified design. The example semiconductor device 200 is a GaN-based structure, including a Si substrate 204, and a GaN layer 206 formed on an upper side of the Si substrate 204, the GaN layer 206 able to act as an epitaxial layer for the semiconductor device 200. In some examples, the GaN layer 206 includes an undoped gallium nitride layer 206a and a carbon doped gallium nitride layer 206b, the undoped gallium nitride layer 206a disposed over the carbon doped gallium nitride layer 206a.

The semiconductor device 200 includes a barrier layer such as an aluminum gallium nitride (AlGaN) layer 208 formed on an upper side of the GaN layer 206. The substrate 204, instead of silicon, can include other suitable substrate material, such as silicon carbide, sapphire, gallium nitride-based substrate. In some examples, the thickness of the AlGaN layer 108 can be in the range of few nanometers (e.g., 5 nm) to a few hundred nanometers (e.g., 300 nm). In some examples, the thickness of GaN layer 206 can be in the range of few nanometers (e.g., 5 nm) to a few microns (e.g., 50 μm).

The GaN layer 206 and the AlGaN layer 208 of the GaN-based semiconductor device 200 of FIG. 2 form a heterojunction with a junction between two materials with different band gaps. The junction provides a 2DEG channel for the semiconductor device 200. Different types of heterojunction semiconductor devices can be used in the respective wafer locations, such as including a junction between gallium arsenide (GaAs) and aluminum gallium arsenide (AlGaAs).

On top of the AlGaN layer, the semiconductor device 200 includes a dielectric layer 210 comprising silicon nitride. In some examples, the dielectric layer 210 can include silicon oxynitride, silicon oxide, Al₂O₃, AlN, or any combination thereof. In some examples, one or more metallization layers are embedded within dielectric layer 210, and some of the metallization layers form a drain electrode, a gate electrode and a source electrode.

The semiconductor device 200 includes a source contact structure 212, a drain contact structure 214, and a gate contact structure 218, each at least partially disposed in the dielectric layer 210. The source contact structure 212 (schematically labeled “S”) (also referred to as a source terminal) is connected to a first conductive feature 213 having a portion accessible at a top side of the semiconductor device 200. The semiconductor device 200 includes a drain contact structure 214 (labeled “D”) (also referred to as a drain terminal) connected to a second conductive feature 215 having an exposed portion accessible at the top side of the semiconductor device 200. The semiconductor device 200 also includes a gate contact structure 216 (labeled “G”) (also referred to as a gate terminal) connected to a third conductive feature 217 having an exposed portion accessible at the top side of the semiconductor device 200. The respective source, drain and gate contact structures 212, 214 and 216 in one example are conductive structures, such as copper, aluminum, tungsten or combinations of these. In one example, the dielectric layer 210 is a multilayer structure and the contact structures 212, 214 and 216 include conductive portions in one or more layers of the multilayer dielectric layer 210. The example gate contact structure 216 is a multi-level shape as shown in FIG. 2, and extends along the channel (along a direction into the page in the view of FIG. 2), with a connection to a conductive routing structure 218 (e.g., copper metallization layer routing features and/or inter-layer vias, etc.) shown in dashed line in FIG. 2. The source contact structure 212 in one example includes field plate portions that extend along the X direction above at least a portion of the gate contact structure 216.

As illustrated in FIG. 2, the drain contact structure 214 is extended compared to the drain contact structure 114 of FIG. 1. In examples in which the drain contact structure 214 extends into the GaN layer 206, the drain contact structure 214 can extend between 0.1 μm and 10 μm into the GaN layer 206. The deeper the drain contact structure 212 extends into the GaN layer 206, the better the GaN-based semiconductor device is shielded from the back-gating effect. However, the depth of the extended drain contact structure 212 can reduce the time-dependent gate oxide breakdown (TDDB) lifetime of the GaN layer 206.

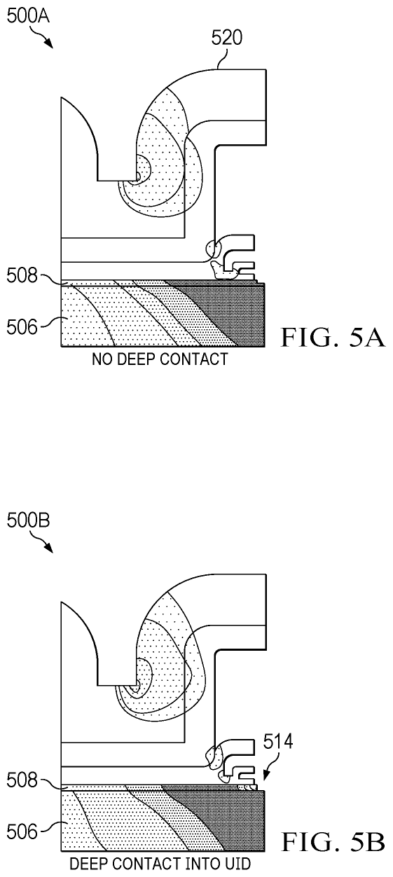

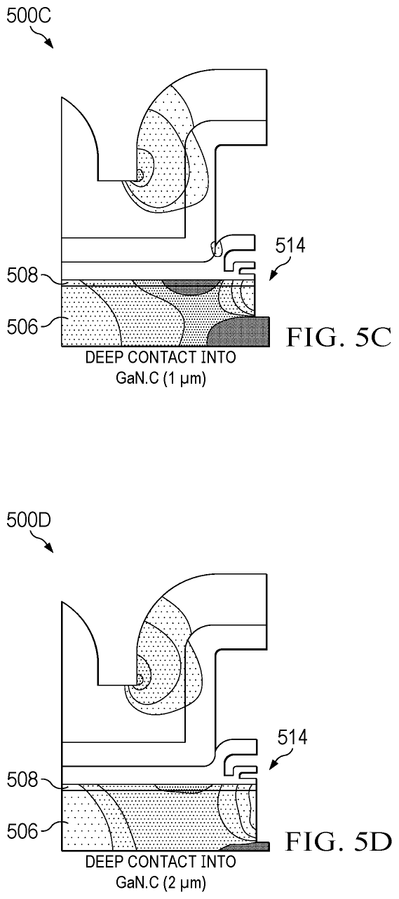

The drain contact structure 214 extends perpendicular to the surface of the GaN layer 206, or in some examples, can extend into the GaN layer 206 at an angle. In some examples, where the GaN layer 206 comprises an undoped GaN layer disposed over a carbon doped GaN layer, the drain contact structure 214 extends through the undoped GaN layer and into the carbon doped GaN layer, as discussed further below in reference to FIGS. 5C and 5D.

By extending the drain contact structure 214 into the GaN layer 206, the vertical electric field between the surface channel and the substrate 204 is reduced, which slows down 2DEG channel depletion due to the back-gating effect. Specifically, the extended drain contact structure 214 provides electric field shielding in the surface channel near the drain contact structure 214. Additionally, the extended drain contact structure 214 can act as normal ohmic contact to 2DEG channel as well as acting as a vertical electric field plate.

In some examples the source contact structure 212 can also be extended (illustrated in dotted lines in FIG. 2) into the GaN layer 206. The source contact structure 212 can extend between 10 μm and 20 μm into the GaN layer 206. In other examples, the source contact structure 212 is a shallow source contact structure. However, where the source contact structure does extend into the GaN layer 206, the source contact structure 212 can extend the same depth as the extended drain contact structure 214, and in other examples, the source contact structure 212 can extend to a different depth into the GaN layer 206 compared to the depth of the extended drain contact structure 214. In some examples, the source contact structure 212 extends perpendicular to the surface of the GaN layer 206, or, in other examples, can extend into the GaN layer 206 at an angle. In some examples, where the GaN layer 206 comprises an undoped GaN layer disposed over a carbon doped GaN layer, the source contact structure 212 extends through the undoped GaN layer and into the carbon doped GaN layer.

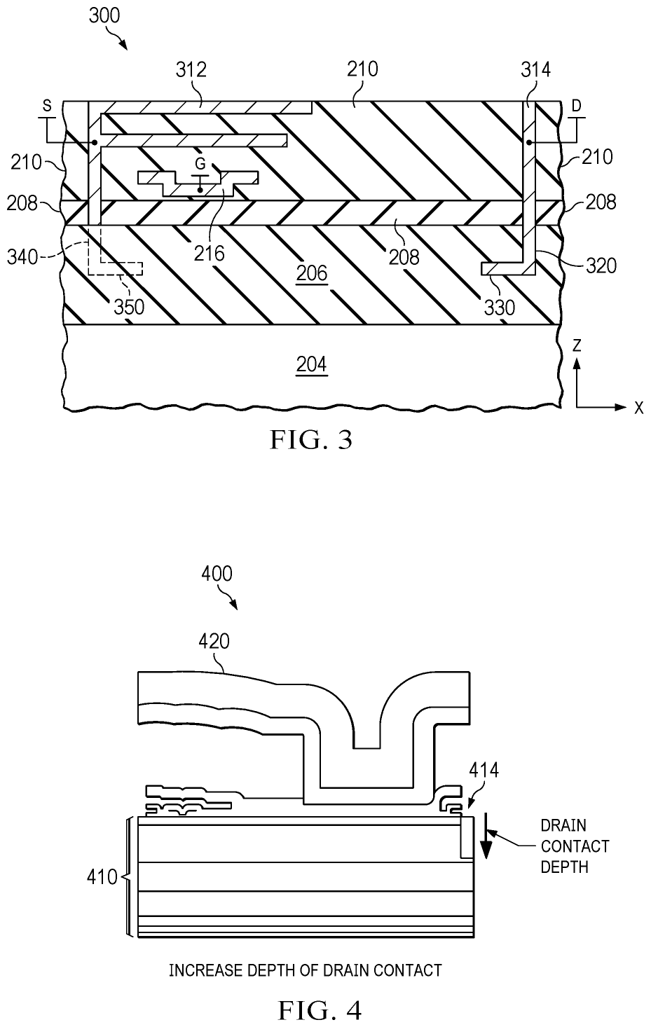

FIG. 3 is an example GaN-based semiconductor device 300 with a modified design. The GaN-based semiconductor device 300 of FIG. 3 is similar to the GaN-based semiconductor device 200 of FIG. 2 but the semiconductor device 300 of FIG. 3 includes a different drain contact structure 314 compared to the extended drain contact structure 214 of FIG. 2. In some examples, the GaN-based semiconductor device 300 can include an extended drain contact structure 314, and the extended drain contact structure can include a first portion 320 that extends down through the dielectric layer 210, through the AlGaN layer 208, and into the GaN layer 206. The extended drain contact structure 314 can also include a second portion 330 coupled to the end of the first portion 320, and the second portion 330 is extends laterally in the GaN layer 206. In some examples, the second portion 330 of the extended drain contact structure 314 is disposed horizontally in the GaN layer 206. For example, the second portion 330 of the extended drain contact structure 314 is horizontally along a plane passing through the GaN layer 206, and is perpendicular to the first portion 320 of the extended drain contact structure 314. In some examples, the second portion 330 of the extended drain contact structure 314 is coupled to the end of the first portion 320 at an angle. In some examples, the second portion 330 of the extended drain contact structure 314 can be a doped layer or a conductive electron/hole channel (i.e., not formed from metal).

Additionally, like with the GaN-based semiconductor device 200 of FIG. 2, the GaN-based semiconductor device 300 of FIG. 3 can include an extended source contact structure 312 that extends into the GaN layer 206. In some examples, the extended source contact structure 312 can include a first portion 340 that extends through the dielectric layer 210, through the AlGaN layer 208, and into the GaN layer 206. The first portion 340 of the extended source contact structure can be disposed in the GaN-based semiconductor device 300 vertically or perpendicular to the top surface of the GaN layer 206. In some examples, the first portion 340 passes through the dielectric layer 210, through the AlGaN layer 208, and into the GaN layer 206 at an angle. The extended source contact structure 312 can also include a second portion 350 coupled to an end of the first portion 340 of the extended source contact structure 312. In some examples, the second portion 350 of the extended source contact structure 314 is disposed horizontally and laterally in the GaN layer 206. For example, the second portion 350 of the extended source contact structure 312 is horizontally along a plane passing through the GaN layer 206, and is perpendicular to the first portion 340 of the extended source contact structure 314. In some examples, the second portion 350 of the extended source contact structure 312 is coupled to the end of the first portion 340 at an angle.

While FIG. 3 illustrates the extended drain contact structure with a horizontal portion 330, a GaN-based semiconductor device 300 may include either the extended drain contact structure 214 of FIG. 2 or the extended drain contact structure 314 of FIG. 3. Similarly, while FIG. 3 illustrates the extended source contact structure 312 with a horizontal portion 350, a GaN-based semiconductor device may include the extended source contact structure 212 of FIG. 2 or the extended source contact structure 312 of FIG. 3.

FIG. 4 is a cross-sectional view of a semiconductor device having the modified design, according to some examples. The semiconductor device 400 of FIG. 4 can be the semiconductor device 200 of FIG. 2. The semiconductor device 400 can be a GaN-based semiconductor device disposed on a substrate (not illustrated in FIG. 4). As mentioned previously, the substrate can be a silicon substrate. The semiconductor device 400 includes an epitaxial layer 410 disposed over the substrate. In some examples, the epitaxial layer 410 includes multiple layers, and in other examples, the epitaxial layer 410 can include a single layer. The epitaxial layer 410 can be a GaN layer or a layer of other semiconductor materials. The semiconductor materials can include group III elements, that is aluminum, gallium, and indium and possibly boron, and provide a portion of the atoms in the semiconductor material. The semiconductor material of the epitaxial layer 410 can also include nitrogen atoms that provide the remainder of the atoms in the semiconductor material. Accordingly, in some examples, the epitaxial layer 410 can include semiconductor material such as gallium nitride, boron gallium nitride, aluminum gallium nitride, indium nitride, and indium aluminum gallium nitride. In one example, epitaxial layer 410 can include an undoped GaN layer 410a on a carbon doped GaN layer 410b. The carbon-doped GaN layer may be formed on several buffer layers each comprising one or more of Ga, Al, In, and N.

The semiconductor device 400 includes a dielectric layer 420. The dielectric layer 420 may be 5 nanometers to 50 nanometers thick and may include one or more layers of silicon dioxide, silicon nitride and/or aluminum oxide. The dielectric layer 420 may be disposed over other layers, such as a field plate dielectric layer, a barrier layer, a cap layer, and a stressor layer.

As illustrated in FIG. 4, the semiconductor device 400 includes an extended drain contact structure 414. The extended drain contact structure 414 can provide electrical connections to a 2DEG channel in the semiconductor device 400. Similar to the extended drain contact structure 214 of FIG. 2, the extended drain contact structure 414 extends into the epitaxial layer 410, and while not illustrated in FIG. 4, the extended drain contact structure 414 extends through the dielectric layer 420 and through other layers on which the dielectric layer 420 is disposed. In some examples, the semiconductor device 400 also includes an extended source contact structure (not illustrated). Like the extended drain contact structure 414, an extended source contact structure can extend into the epitaxial layer 410, and can extend through the dielectric layer 420 and through other layers on which the dielectric layer 420 is disposed (e.g., field plate dielectric layer, barrier layer, cap layer, stressor layer).

FIG. 5A-5D illustrate exemplary semiconductor devices with drain contract structures of differing depths, according to some examples. FIG. 5A illustrates a GaN-based semiconductor device 500A with a drain contract contact structure that does not extend into the AlGaN layer 508 or into the GaN layer 506. FIG. 5B illustrates a GaN-based semiconductor device 500B with a drain contact structure that extends into and through the AlGaN layer 508 but does not extend into the GaN layer 506. FIG. 5C illustrates a GaN-based semiconductor device 500C with a drain contact structure 514 that extends into and through the AlGaN layer 508 and into the GaN layer 506. The drain contract structure 514 of the GaN-based semiconductor device 500C extends into the GaN layer to a depth of 1 μm. FIG. 5D illustrates a GaN-based semiconductor device 500D with a drain contact structure 514 that extends into and through the AlGaN layer 508 and into the GaN layer 506. The drain contact structure 514 of the GaN-based semiconductor device 500D extends into the GaN layer 506 to a depth of 2 μm.

As illustrated in FIGS. 5A-5D, the vertical electric field reduces in strength as the drain contact structure 514 extends further into the AlGaN layer 508 and into the GaN layer 506. For example, the vertical electric field at or near the drain contact structure 514 is greater with the GaN-based semiconductor device 500A than the GaN-based semiconductor device 500B because the drain contact structure 514 of the GaN-based structure 500B extends further into the AlGaN layer 508 than the drain contract structure 514 of the GaN-based structure 500A. Similarly, the vertical electric field at or near the drain contact structure 514 is greater with the GaN-based semiconductor device 500B than the GaN-based semiconductor device 500c because the drain contact structure 514 of the GaN-based structure 500c extends through the AlGaN layer 508 and into the GaN layer 506 while the drain contract structure 514 of the GaN-based structure 500B only extends into the AlGaN layer 508 but not the GaN layer 506. The vertical electric field at or near the drain contact structure 514 is greater with the GaN-based semiconductor device 500D than the GaN-based semiconductor device 500C because the drain contact structure 514 of the GaN-based structure 500D extends further into the GaN layer 506 than the drain contract structure 514 of the GaN-based structure 500C. Accordingly, as illustrated, the further the drain contact structure extends into the AlGaN layer 508 and into the GaN layer 506, the more the vertical electrical field is reduced.

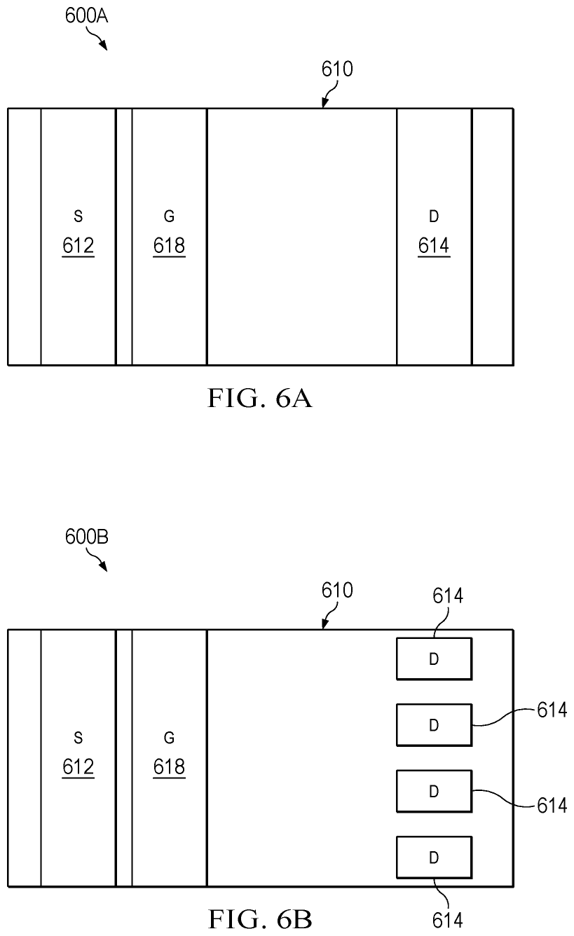

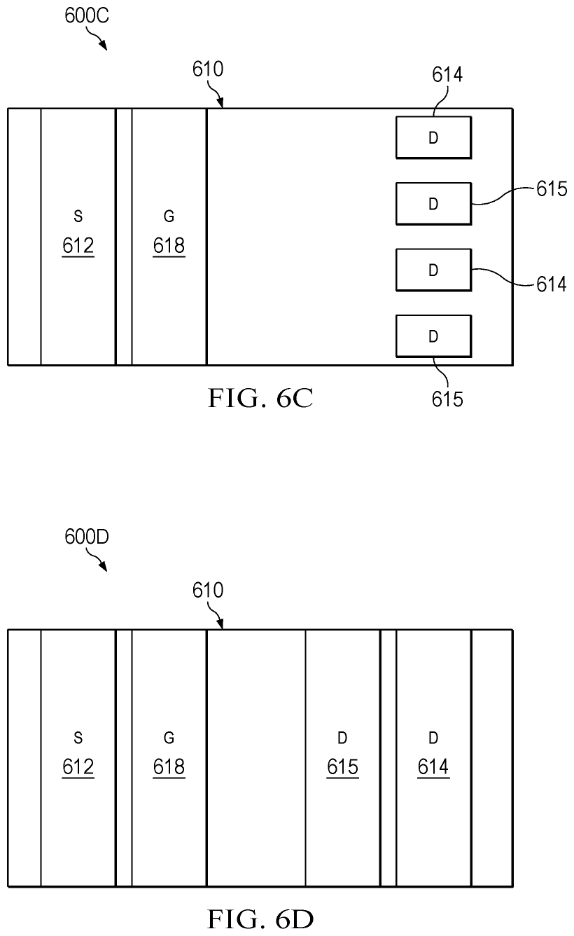

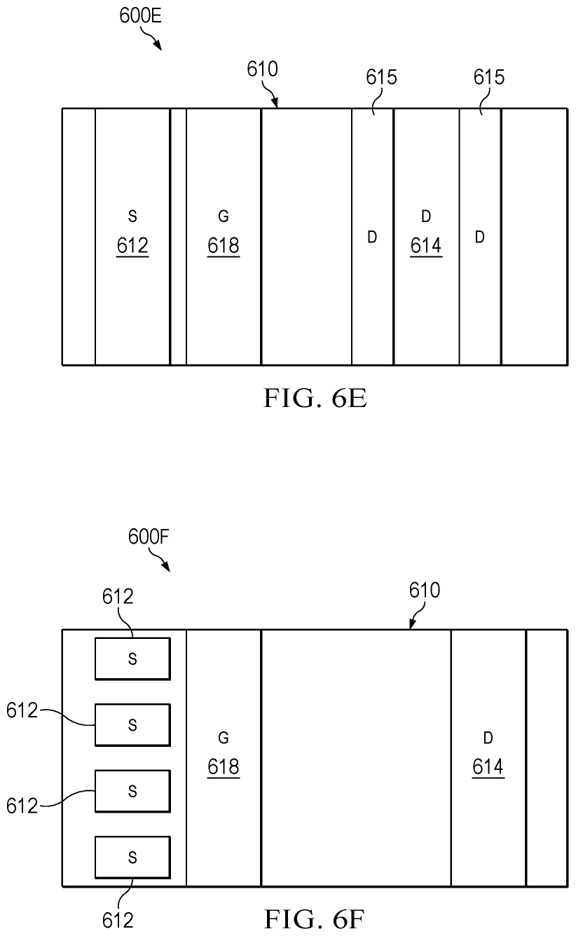

FIG. 6A is a a top view of a cross-section of a GaN-based semiconductor device, such as the GaN-based semiconductor device 100 of FIG. 1 without an extended drain contact structure. The GaN-based semiconductor device 600A includes a source contact structure 612, a gate contact structure 618, and a drain contact structure 614. The source contact structure 612, the gate contact structure 618, and the drain contact structure 614 are disposed on a substrate 610. The substrate 610 can include a dielectric layer and other layers. In other examples, the substrate 610 can include a SiN layer (e.g., SiN layer 210 of FIG. 2), an AlGaN layer (e.g., AlGaN layer 208 of FIG. 2), and a GaN layer (e.g., GaN layer 206 of FIG. 2). For illustrative purposes, FIG. 6A is a top cross-sectional view of the semiconductor device and the substrate 610 illustrates is the SiN layer (e.g., SiN layer 210 of FIG. 2).

As illustrated in FIG. 6A, the source contact structure 612, the gate contact structure 618, and the drain contact structure 614 span the width of the GaN-based semiconductor device 600A. Accordingly, in some examples, the source contact structure 612, the gate contact structure 618, and the drain contact structure 614 have similar dimensions. For example, the drain contact structure 614 can have the same length as the source contact structure 612.

The GaN-based semiconductor device 600A can have other dimensions for the source contact structure 612, the gate contact structure 618, and the drain contact structure 614. Like FIG. 6A, FIGS. 6B-6C are top views of cross-sections of different GaN-based semiconductor devices with different dimensions for the source contact structure 612, the gate contact structure 618, and the drain contact structure 614.

FIG. 6B is a top view of a cross-section of a GaN-based semiconductor device 600B, according to some examples. For illustrative purposes, FIG. 6B is a top cross-sectional view of the semiconductor device 600B and the substrate 610 illustrated is the SiN layer (e.g., SiN layer 210 of FIG. 2). The GaN-based semiconductor device 600B includes a source contact structure 612, a gate contact structure 618, and multiple drain contact structures 614. While the source contact structure 612 and the gate contact structure 618 of GaN-based semiconductor device 600B are similar to the source contact structure 612 and the gate contact structure 618 of GaN-based semiconductor device 600A, the drain contact structure 614 of GaN-based semiconductor device 600C is different from the drain contact structure 614 of GaN-based semiconductor device 600A. As illustrated in FIG. 6B, multiple drain contact structures 614 replace the single drain structure 614 of GaN-based semiconductor device 600A.

FIG. 6C is a top view of a cross-section of a GaN-based semiconductor device 600C, according to some examples. For illustrative purposes, FIG. 6C is a top cross-sectional view of the semiconductor device 600C and the substrate 610 illustrated is the SiN layer (e.g., SiN layer 210 of FIG. 2). The GaN-based semiconductor device 600C includes a source contact structure 612, a gate contact structure 618, and multiple drain contact structures 614. While the source contact structure 612 and the gate contact structure 618 of GaN-based semiconductor device 600C are similar to the source contact structure 612 and the gate contact structure 618 of GaN-based semiconductor device 600A, the drain contact structure 614 of GaN-based semiconductor device 600C is different from the drain contact structure 614 of GaN-based semiconductor device 600A. As illustrated in FIG. 6C, multiple drain contact structures 614 replace the single drain structure 614 of GaN-based semiconductor device 600A.

Further, as illustrated, the GaN-based semiconductor device 600C can include drain contact structures 615 in addition to the drain contract structures 614 of GaN-based semiconductor devices 600C. As mentioned previously, the deeper the drain contact structure, the better the shielding effect produced. The drain contact structure still also needs to allow the current to flow from the source to the drain. The resistance of the drain contact structure can be higher to account for the depth of the drain contact structure. Accordingly, in some examples, the drain contact structures 615 can have different depths as compared to the drain contact structure 614. For example, the drain contact structures 615 can be shallower drain contact structures optimized for contact resistance, while the drain contact structures 614 can be deeper drain contact structures for maximizing the shielding effect.

The GaN-based semiconductor device 600C can have any arrangement of multiple drain contact structures 614, 615. For example, the GaN-based semiconductor device 600C can have two rows of drain contact structures 614, 615: one row comprising shallower drain contact structures 615 closer to the gate contact structure 618, and another row comprising deeper drain contact structures 614 further from the gate contact structure 618 and disposed on an opposite side of the drain contact structures 615. In another example, the GaN-based semiconductor device 600C can include a larger drain contact structure 614, like the drain contact structure 614 of the GaN-based semiconductor device 600A, and smaller drain contact structures 615 (like those illustrated in FIG. 6C) disposed as a row of drain contact structures disposed on either side of the singular drain contact structure 614.

FIG. 6D is a top view of a cross-section of a GaN-based semiconductor device 600D, according to some examples. For illustrative purposes, FIG. 6D is a top cross-sectional view of the semiconductor device 600D and the substrate 610 illustrated is the SiN layer (e.g., SiN layer 210 of FIG. 2). The GaN-based semiconductor device 600D includes a source contact structure 612, a gate contact structure 618, and multiple drain contact structures 614, 615. The source contact structure 612 and the gate contact structure 618 of GaN-based semiconductor device 600C are similar to the source contact structure 612 and the gate contact structure 618 of GaN-based semiconductor device 600A. Like the GaN-based semiconductor device 600C, the GaN-based semiconductor device 600D includes multiple drain contact structures: a drain contact structure 614 similar to the drain contact structure 614 of GaN-based semiconductor device 600A, and another drain contact structure 615 having a similar shape and arrangement as drain contact structure 614 but having a depth shallower than the drain contact structure 614. As mentioned with FIG. 6C, the GaN-based semiconductor device 600D can include drain contact structures of different depths: the drain contact structure 615 can be shallower drain contact structures optimized for contact resistance, while the drain contact structures 614 can be deeper drain contact structures for maximizing the shielding effect. As illustrated, the drain contact structures 614 and 615 of the GaN-based semiconductor device 600D are separated by the SiN layer 610.

FIG. 6E is a top view of a cross-section of a GaN-based semiconductor device 600E, according to some examples. For illustrative purposes, FIG. 6E is a top cross-sectional view of the semiconductor device 600E and the substrate 610 illustrated is the SiN layer (e.g., SiN layer 210 of FIG. 2). The GaN-based semiconductor device 600E includes a source contact structure 612, a gate contact structure 618, and multiple drain contact structures 614. The source contact structure 612 and the gate contact structure 618 of GaN-based semiconductor device 600C are similar to the source contact structure 612 and the gate contact structure 618 of GaN-based semiconductor device 600A. Like the GaN-based semiconductor device 600C and the GaN-based semiconductor device 600D, the GaN-based semiconductor device 600E includes multiple drain contact structures: drain contact structure 614 similar to the drain contact structure 614 of GaN-based semiconductor device 600A, and drain contact structures 615 having a similar shape and arrangement as drain contact structures 614 but having a depth shallower than the drain contact structures 614. As mentioned with FIGS. 6C and 6D, the GaN-based semiconductor device 600E can include drain contact structures of different depths: the drain contact structures 615 can be shallower drain contact structures optimized for contact resistance, while the drain contact structure 614 can be deeper drain contact structures for maximizing the shielding effect. As illustrated, the drain contact structures 615 of the GaN-based semiconductor device 600D are disposed on adjacent sides of the of the drain contact structure 614.

FIG. 6F is a top view of a cross-section of a GaN-based semiconductor device 600F, according to some examples. The GaN-based semiconductor device 600F includes multiple source contact structures 612, a gate contact structure 618, and a drain contact structure 614. While the drain contact structure 614 and the gate contact structure 618 of GaN-based semiconductor device 600F are similar to the drain contact structure 614 and the gate contact structure 618 of GaN-based semiconductor device 600A, the source contact structure 612 of GaN-based semiconductor device 600F is different from the source contact structure 612 of GaN-based semiconductor devices 600A, 600B, 600C, 600D, and 600E. As illustrated in FIG. 6F, multiple source contact structures 612 replace the single source structure 612 of GaN-based semiconductor devices 600A, 600B, 600C, 600D, and 600E.

In some examples, the multiple source contact structures 612 of the GaN-based semiconductor device 600F can be combined with the multiple drain contact structures 614, 615 of the GaN-based semiconductor device 600B, the GaN-based semiconductor device 600C, the GaN-based semiconductor device 600D, or the GaN-based semiconductor device 600E. In some examples, the GaN-based semiconductor devices 600A-F can have multiple gate contact structures: for example, the GaN-based semiconductor device can have multiple gate contact structures, similar to the multiple drain contact structures 614, 615 of FIGS. 6A-6F, and to the multiple source contact structures 612 of the GaN-based semiconductor device 600F.

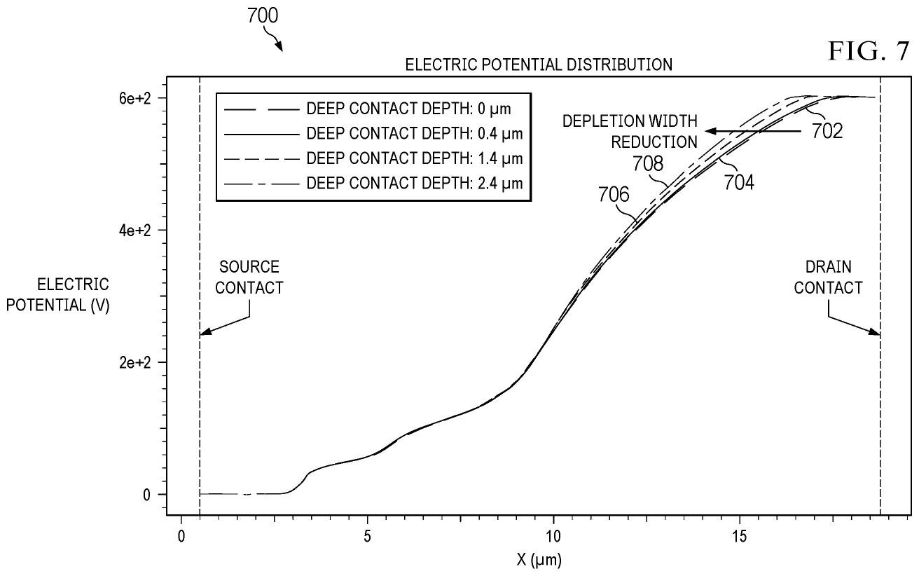

FIG. 7 illustrates the electrical potential distribution across the semiconductor device from the source contact structure to the drain contact structure. The graph 700 illustrates the electrical potential distribution for four GaN-based semiconductor devices (e.g., GaN-based semiconductor devices 500A-D of FIGS. 5A-5D). Each of the four-GaN-based semiconductor devices have different drain contact depths. The graph 700 specifically plots the electrical potential distribution of GaN-based semiconductor devices at a particular location on each of the GaN-based semiconductor device between the respective source contact structure and the respective drain contact structure of the respective GaN-based semiconductor device.

Result 702 shows the electric potential distribution for a GaN-based semiconductor device having a drain contact structure that does not extend into the AlGaN layer or into the GaN layer, such as the GaN-based semiconductor device 500A of FIG. 5A. Result 704 shows the electric potential distribution for a GaN-based semiconductor device having a drain contact structure that does extend into the AlGaN layer but not into the GaN layer, such as the GaN-based semiconductor device 500B of FIG. 5B. For example, the drain contact structure for this GaN-based semiconductor device extends 0.4 μm into the AlGaN layer. Result 706 shows the electric potential distribution for a GaN-based semiconductor device having a drain contact structure that extends into the AlGaN layer and into the GaN layer, such as the GaN-based semiconductor device 500C of FIG. 5C, at a depth of 1.4 um. Result 708 shows the electric potential distribution for a GaN-based semiconductor device having a drain contact structure that extends into the AlGaN layer and into the GaN layer, such as the GaN-based semiconductor device 500D of FIG. 5D, at a depth of 2.4 μm.

As illustrated in FIG. 7, the results showing the electric potential distribution differ based on proximity to the drain contact structure of the respective GaN-based semiconductor device. For example, comparing results 702 and 708, a GaN-based semiconductor device with an extended drain contact structure having a depth of 2.4 um has more electric potential compared to the electric potential of a GaN-based semiconductor device without an extended drain contact structure. As shown, consistent to the vertical electrical field trend, the depletion width of the electric potential under high voltage is reduced with deeper drain contact structures. For example, a GaN-based semiconductor device without an extended drain contact structure has a larger width of electric potential depletion as compared to the smaller width of electric potential depletion of a GaN-based semiconductor device with an extended drain contact. With a deeper drain contact structure, the total depletion (from the source to drain at 600V) is reduced because of the reduction of the back-gating effect. The reduction in the total depletion can improve reliability margin. Further, the reliability margin can be used to reduce gate-to-drain distance. The reduction of electric potential depletion width is based on the suppression of vertical electrical field from the substrate of the semiconductor device.

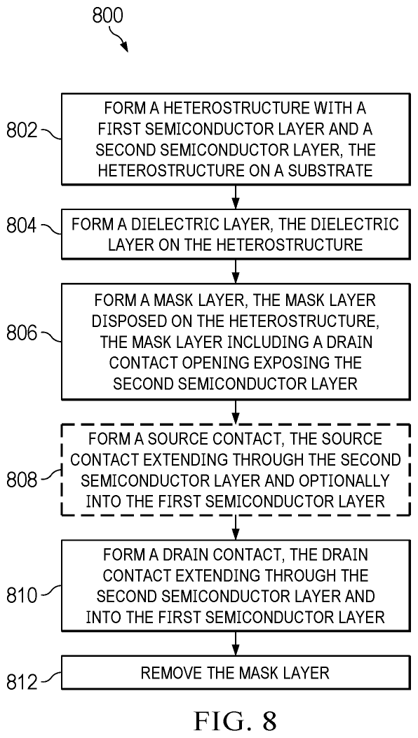

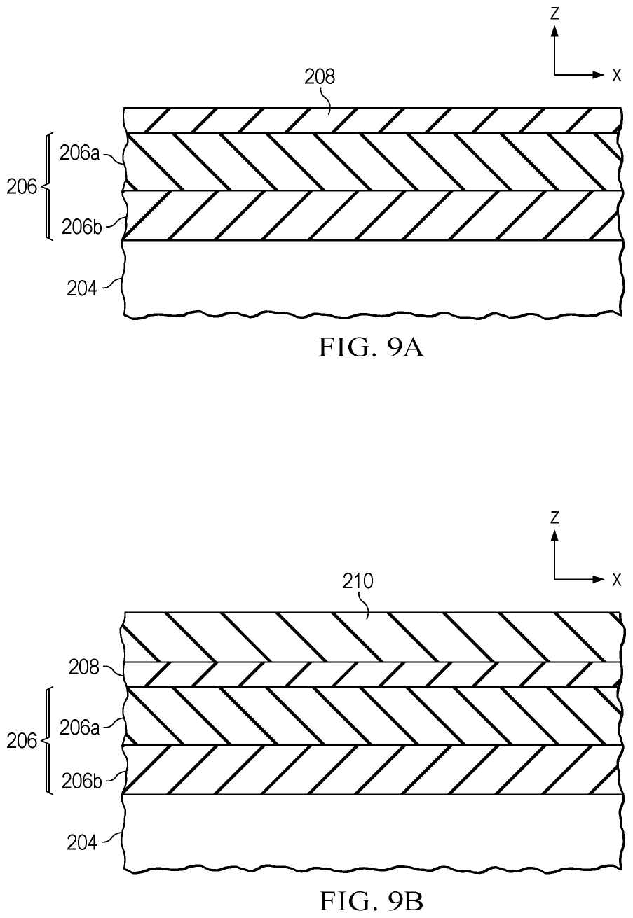

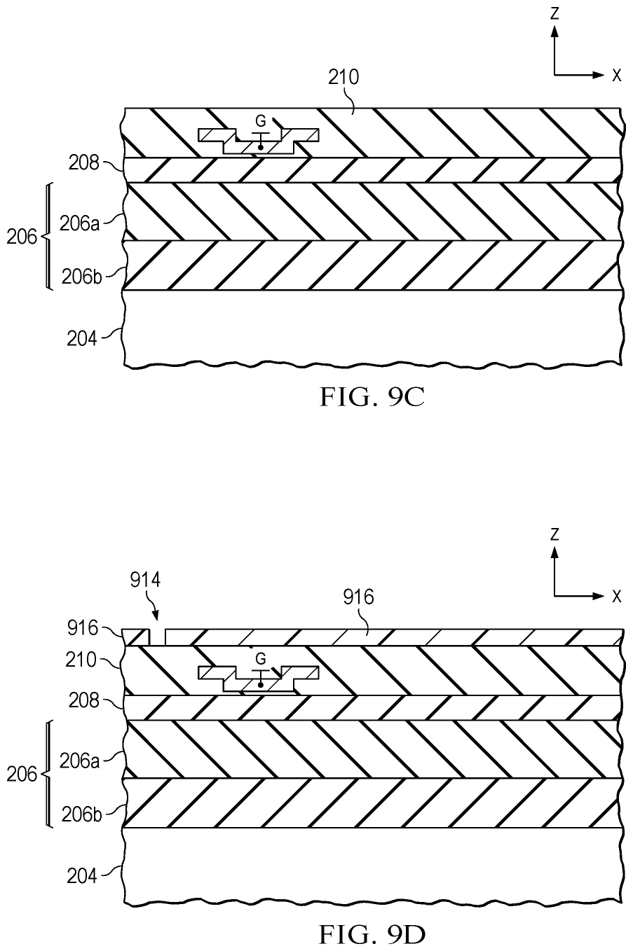

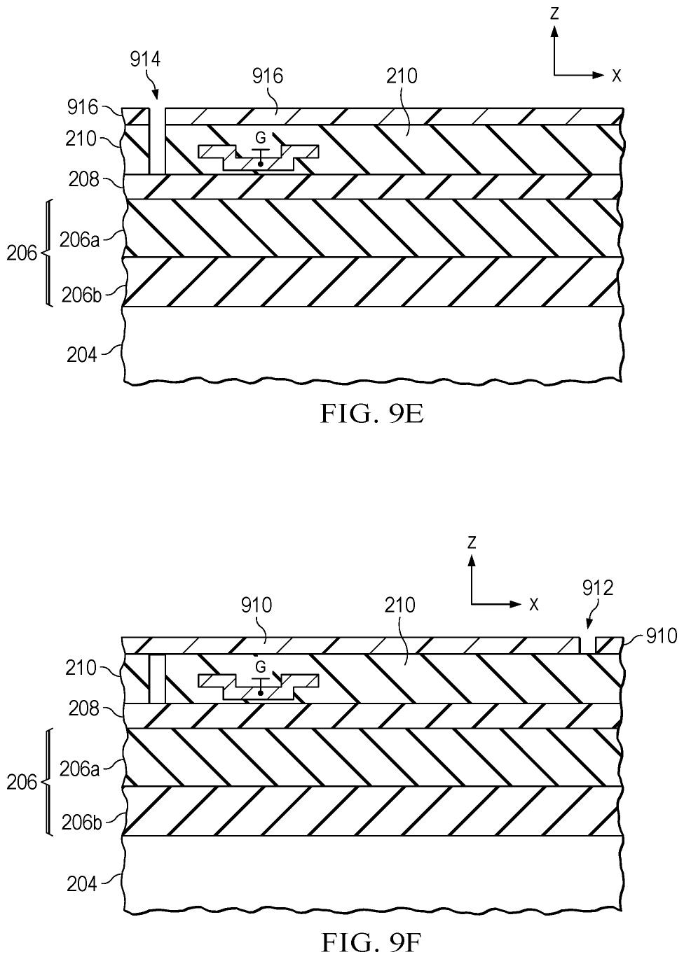

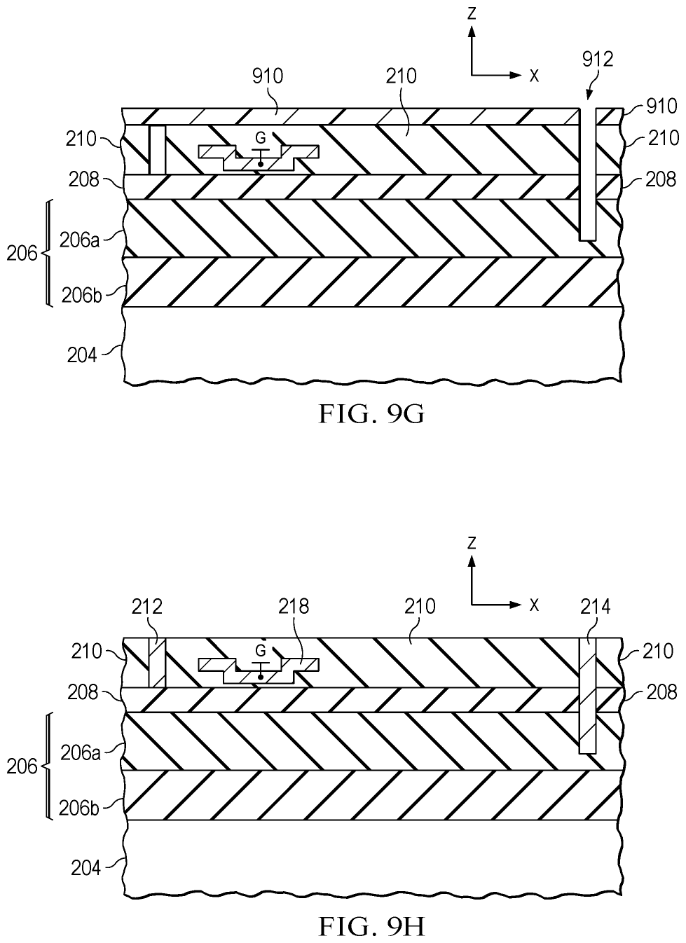

FIG. 8 is a flowchart of operations for manufacturing a semiconductor device, such as the GaN-based device 200 of FIG. 2, according to some examples. FIGS. 9A-9H are cross-sectional views of a semiconductor device during manufacturing, each of the views corresponding to the operations of FIG. 8. The method 800 as discussed below is an example of operations for manufacturing a semiconductor device, such as the GaN-based device 200 of FIG. 2, and other examples of the operations can involve variations of the manufacturing process discussed herein.

The method 800 begins with forming a first semiconductor layer and a second semiconductor layer, which includes forming a heterostructure, the heterostructure disposed on a substrate 204 (step 802), as illustrated in FIG. 9A. The heterostructure, in some examples, includes the first semiconductor layer (e.g., the GaN layer 206), and the second semiconductor layer (e.g., the AlGaN layer 208). The heterostructure is disposed on the substrate 204. The heterostructure is grown on the seed layer using chemical vapor deposition or using other suitable deposition processes. For illustrative purposes, it is assumed that the substrate 204 includes silicon. In some examples, where the heterostructure includes the GaN layer 206 and the AlGaN layer 208, the AlGaN layer 208, having a top side, is grown on the GaN layer 206. A 2DEG channel is formed at the interface between the AlGaN layer 208 and the GaN layer 206. The AlGaN layer 208 forms when aluminum nitride (AlN) is deposited using molecular beam epitaxy on the GaN layer 206. In some examples, other types of deposition methods, such as metalorganic chemical vapor deposition can be used to deposit AlN on the GaN layer 206. The AlGaN layer 208 and the GaN layer 206, due to proportionality discontinuity, form the 2DEG channel at the interface between the AlGaN layer 208 and the GaN layer 206.

Following growing the AlN layer on the GaN layer to form the AlGaN layer, the method 800 moves to a step 804 that includes forming dielectric layer and other layers on top of the AlGaN layer, which can include depositing the dielectric layer 210, as shown in FIG. 9B. The dielectric layer can include SiN, and is grown on top of the heterostructure. The dielectric layer deposited can include any number of individual dielectric layers, such as pre-gate layers, pre-metal dielectric layers, intrametal dielectric layers, and others. Some or all of which may comprise SiN.—Metallization layers and vias may be embedded within the dielectric layer. In some examples, the dielectric layer 210 can be grown on top of the AlGaN layer. The dielectric layer may be grown by low pressure chemical vapor deposition (LPCVD), atomic layer deposition (ALD), plasma enhanced chemical vapor deposition (PECVD), or other thin film deposition techniques.

In some examples, the method 800 includes forming the gate in the dielectric layer, as illustrated in FIG. 9C. In some examples, the method 800 can involve forming etched portions for the gate contact structure 218. In some examples, the method 800 can involve metal deposition processes or any other process used to form the gate of the GaN-based device 200 of FIG. 2 and the gate contact structure 218.

In some examples, the method 800 includes forming a mask layer 916 on the dielectric layer, the mask layer including an opening 914 for a source contact structure 212, as illustrated in FIG. 9D. The opening 914 for the source contact structure exposes the dielectric layer 210 for forming the source contact structure. Forming the mask layer 916 can involve forming a dry film or a photoresist film on top of the dielectric layer 210 through a suitable coating process, which may be followed by curing, descum. After the mask layer 916 is formed, lithography technology and/or etching processes can occur, such as a dry etch and/or wet etch process to form etched portions which extend from the top side of the dielectric layer 210 to the AlGaN layer 208 for the source contact structure 212, as illustrated in FIG. 9E. The method 800 can include removing the mask layer 916 before forming the mask layer 910.

The method 800 proceeds with forming a mask layer 910 on the dielectric layer, the mask layer 910 including an opening 912 for a drain contact structure 214 (step 806), as illustrated in FIG. 9F. The opening 912 for the drain contact structure 214 exposes the dielectric layer 210 for later steps for forming the drain contact structure 214. Forming the mask layer 910 can involve forming a dry film or a photoresist film on the top of the dielectric layer 210 through a suitable coating process, which may be followed by curing, descum. In some examples, the mask layer 910 can include other openings for additional drain contact structures. Accordingly, the mask layer 910 can include any number of openings to accommodate the drain contact structure arrangements (e.g., drain contact structure arrangements illustrated in FIGS. 6A-6I) as described herein. The mask layer 910 can cover any etched portions for the source contact structure 212.

In some examples, the mask layer 910 can include openings for forming both an extended drain contact structure 214 (as illustrated in FIG. 2) and an extended source contact structure 212 (as illustrated in dotted lines in FIG. 2). As mentioned, the method 800 can involve forming the source contact structure 212. In some examples, the source contact structure 212 is formed at the same time that the drain contact structure 214 is formed, and accordingly, the opening 914 of mask layer 916 is included in the mask layer 910 for etching the source contact structure 214. Any of the mask layers (either mask layer 910 or mask layer 916) can include openings for additional source contact structures.

In some examples, if the extended drain contact structure 214 increases the contact resistance, the extended drain contact structure 214 can then only be added on the drain side of the GaN-based semiconductor device and the source contact structure 212 is not extended. Accordingly, as illustrated in FIGS. 9D-9F, the method 800 includes forming a first mask layer (e.g., mask layer 916) on the dielectric layer 210, the first mask layer 916 including an opening (e.g., opening 914) for the source contact structure, as illustrated in FIG. 6D, and then the method 800 can include forming a second mask layer (e.g., mask layer 910) on the dielectric layer 210, the second mask layer including the opening (e.g., opening 912) for the drain contact structure, as illustrated in FIG. 6F.

After forming the mask layer 910 or other mask layers, the method 800 includes lithography technology and/or etching processes, such as a dry etch and/or wet etch process to form etched portions which extend from the top side of the dielectric layer 210 to the AlGaN layer 208 for the drain contact structure 214 and the source contact structure 212, as illustrated in FIG. 9G. Accordingly, the method 800 involves forming a drain contact (step 810) using an etching process at the opening 912 of the mask layer 910, which extends through the dielectric layer 210 to the AlGaN layer 208. Further, in some examples, the method 800 includes forming the source contact structure 212 (step 808) using an etching process or other process at the opening 914 of the mask layer 916. While the source contact structure 212 is illustrated as being formed before the drain contact structure 214, the source contact structure 212 can be formed after or at the same time as the drain contact structure 214.

When etching the drain contact 214, the etched portions extend from the top side of the dielectric layer 210 through the AlGaN layer 208 and into the GaN layer 206 and into the GaN layer 206 for the drain contact structure 214, as illustrated in FIG. 9G. Accordingly, the step 810 of method 800, in which a drain contact is formed, further includes using an etching process at the opening 912 of the mask layer 910 to extend the drain contact structure 214 through the dielectric layer 210 into the AlGaN layer 208 and into the GaN layer 206. In some examples, a different mask layer can be used for etching the deeper etched portions of the drain contact structure 214 but not etching the source contact structure 212, as illustrated in FIG. 9F and FIG. 9G. As illustrated in FIGS. 9F and 9G, the mask layer 910 can cover the etched portions of the source contact structure and an etching process happens at opening 912 for the drain contact structure 214. In some examples, a single mask layer (e.g., mask layer 910) can be used with openings for both the drain contact structure 214 and a source contact structure 212, and in such examples, both drain contact structure 214 and the source contact structure 212 can be further etched into the GaN layer 206.

In some examples, the method 800 involves etching into the AlGaN layer 208 and into the GaN layer 206 for both the source contact structure 212 and for the drain contact structure 214. In other examples, the method 800 involves etching into the AlGaN layer 208 and into the GaN layer 206 for the drain contact structure 214 and into the AlGaN layer 208 but not the GaN layer 206 for the source contact structure 212.

The method 800 proceeds with removing the mask layer to finish processing the GaN-based device (step 812), as illustrated in FIG. 9H. In some examples, where the method 800 involves having two mask layers, both mask layers are removed, and in further examples, the mask layers can be removed at different times for the formation of the drain contact structure 214 and for the formation of the source contact structure 212.

The method 800 proceeds with forming the drain contact structure 214 by a deposition process (sputter, evaporation, etc.), as illustrated in FIG. 9H. In some examples, the source drain contact 212 can be formed simultaneously as the drain contact structure 214, as illustrated in FIG. 9H. A deposition process can deposit material into the formed drain contact to form the drain contact structure 214 that extends through the AlGaN layer 208 and into the GaN layer 206

In some examples, the method 800 further continues with back end of line (BEOL) processing and with other processes to complete the GaN-based device, such as forming the top metals disposed on the GaN-based device 200.

In the foregoing discussion and in the claims, the terms “including” and “comprising” are used in an open-ended fashion, and thus should be interpreted to mean “including, but not limited to . . . .” Also, the term “couple” or “couples” is intended to mean either an indirect or direct connection. Thus, if a first device couples to a second device, that connection may be through a direct connection or through an indirect connection via other devices and connections. Similarly, a device that is coupled between a first component or location and a second component or location may be through a direct connection or through an indirect connection by other devices and connections. An element or feature that is “configured to” perform a task or function may be configured (e.g., programmed or structurally designed) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof. Additionally, uses of the phrases “ground” or similar in the foregoing discussion are intended to include a chassis ground, an Earth ground, a floating ground, a virtual ground, a digital ground, a common ground, and/or any other form of ground connection applicable to, or suitable for, the teachings of the present disclosure. Unless otherwise stated, “about,” “approximately,” or “substantially” preceding a value means+/−10 percent of the stated value.

The above discussion is meant to be illustrative of the principles and various embodiments of the present disclosure. Numerous variations and modifications will become apparent to those skilled in the art once the above disclosure is fully appreciated. It is intended that the following claims be interpreted to embrace all such variations and modifications.

What is claimed is:

1. A semiconductor device, comprising:
a silicon substrate layer;
a first semiconductor layer comprising a gallium nitride layer, the first semiconductor layer disposed over the silicon substrate layer;
a second semiconductor layer disposed on the first semiconductor layer, the second semiconductor layer comprising an aluminum gallium nitride layer; and
a first drain contact extending through the second semiconductor layer and extending into the first semiconductor layer.

2. The semiconductor device of claim 1, wherein the first drain contact comprises a first portion that extends into the first semiconductor layer, and the first portion extends between about 0.1 μm and about 10 μm into the first semiconductor layer.

3. The semiconductor device of claim 1, further comprising a dielectric layer disposed on the second semiconductor layer, the dielectric layer having at least one metallization layer embedded therein.

4. The semiconductor device of claim 1, wherein the first drain contact comprises:
a first portion that extends into the first semiconductor layer; and
a second portion that extends laterally in the first semiconductor layer.

5. The semiconductor device of claim 1, further comprising a source contact extending through the second semiconductor layer and into the first semiconductor layer.

6. The semiconductor device of claim 1, further comprising a second drain contact extending through the second semiconductor layer and into the first semiconductor layer.

7. The semiconductor device of claim 6, wherein the second drain contact is separated from the first drain contact by the first semiconductor layer, wherein the second drain contact is disposed adjacent to and in line with the first drain contact.

8. The semiconductor device of claim 1, wherein the gallium nitride layer comprises an undoped gallium nitride layer disposed over a carbon doped gallium nitride layer.

9. The semiconductor device of claim 8, wherein the first drain contact extends through the undoped gallium nitride layer and into the carbon doped gallium nitride layer.

10. The semiconductor device of claim 1, wherein the first drain contact comprises a singular elongated drain contact.

11. The semiconductor device of claim 1, further comprising a shallow source contact.

12. The semiconductor device of claim 1, further comprising a first shallow drain contact.

13. The semiconductor device of claim 12, wherein the first shallow drain contact disposed adjacent to the first drain contact.

14. The semiconductor device of claim 12, further comprising a second shallow drain contact, wherein the second shallow drain contact is disposed adjacent to the first drain contact and opposite the first shallow drain contact.

15. A method for manufacturing a semiconductor device, the method comprising:
forming a first semiconductor layer on a semiconductor substrate, the first semiconductor layer comprising a gallium nitride layer;
forming a second semiconductor layer on the first semiconductor layer, the second semiconductor layer comprising an aluminum gallium nitride layer;
forming a mask layer on the second semiconductor layer, the mask layer comprising an opening exposing the second semiconductor layer;
forming a drain contact using the opening of the mask layer exposing the second semiconductor layer, the drain contact extending through the second semiconductor layer and into the first semiconductor layer.

16. The method of claim 15, further comprising:
forming a source contact by a source contact opening of the mask layer, the source contact via exposing the second semiconductor layer.

17. The method of claim 15, further comprising forming a drain contact that extends into the first semiconductor layer by a deposition process into the drain contact.

18. The method of claim 15, wherein the drain contact extends between 1 μm and about 2 μm into the first semiconductor layer.

19. The method of claim 15, further comprising forming a second drain contact by using a second drain opening of the mask layer, the second drain contact extending through the second semiconductor layer and into the first semiconductor layer.

20. The method of claim 15, wherein the drain contact extends into a gallium nitride layer of the first semiconductor layer.

21. The method of claim 15, further comprising forming a dielectric layer disposed on the second semiconductor layer, the dielectric layer having at least one metallization layer.

22. A structure, comprising:
a gallium nitride layer disposed on a silicon substrate;
an aluminum gallium nitride layer disposed on the gallium nitride layer;
a silicon nitride layer disposed on the aluminum gallium nitride layer;
at least one metallization layers disposed in the silicon nitride layer, the at least one metallization layers forming a drain electrode, a gate electrode, and a source electrode; and
at least one drain terminal extending through the silicon nitride layer and aluminum gallium nitride layer and into the gallium nitride layer, the at least one drain terminal coupled to the drain electrode.

23. The structure of claim 22, further comprising a source terminal extending through the silicon nitride layer and through the aluminum gallium nitride layer, the source terminal coupled to the source electrode.

24. The structure of claim 22, wherein the at least one drain terminal comprises:
a first portion extending through the silicon nitride layer and through aluminum gallium nitride layer; and
a second portion disposed in the gallium nitride layer and extending along and parallel to a horizontal plane passing through the gallium nitride layer.
